(19) United States
(12) Patent Application Publication
(10) Pub. No.: US 2017/0179222 A1
(43) Pub. Date: Jun. 22, 2017

(54) SEMICONDUCTOR DEVICE

(71) Applicant: SHARP KABUSHIKI KAISHA, Sakai City, Osaka (JP)

(72) Inventors: Shinichi HANDA, Osaka (JP); Masaru KUBO, Osaka (JP)

(73) Assignee: SHARP KABUSHIKI KAISHA, Sakai City, Osaka (JP)

(21) Appl. No.: 15/115,958

(22) PCT Filed: Dec. 16, 2014
(86) PCT No.: PCT/JP2014/083295

§ 371 Date: Aug. 2, 2016

(30) Foreign Application Priority Data
Feb. 25, 2014 (JP) 2014-034330

(51) Int. Cl. H01L 29/06; H01L 29/778; H01L 29/20; H01L 23/31; H01L 23/00

(52) U.S. Cl. CPC H01L 29/0619; H01L 23/3192; H01L 23/564; H01L 29/2003; H01L 29/7786; H01L 29/0649

(57) ABSTRACT

A semiconductor device includes a wall-like first guard ring structure that is formed to surround a periphery of an element formation region on a semiconductor substrate and that extends in a thickness direction of the substrate through an insulating film; and a wall-like second guard ring structure that is formed to surround the periphery of the element formation region between the element formation region on the semiconductor substrate and the first guard ring structure and that extends in the thickness direction of the substrate through the insulating films. The first and second guard ring structures are formed of a conductive material, and the first guard ring structure is provided in a state of being insulated from the semiconductor substrate, the element formation region and the second guard ring structure.

### TECHNICAL FIELD

The present invention relates to a semiconductor device, and, specifically, a semiconductor device provided with a guard ring structure that prevents chipping due to dicing or the infiltration of moisture into a semiconductor element such as a transistor.

### BACKGROUND ART

In the related art, semiconductor devices provided with semiconductor elements such as transistors are taken from a wafer by dicing the wafer into individual chips. When dividing a wafer into chips, there are cases where chipping or cracking occurs at dicing cross section due to the impact caused by the dicing. Since moisture or mobile ions may infiltrate from the dicing cross section of a semiconductor device, which is taken from a wafer by dicing, wiring may corrode, the resistance of an insulating film may deteriorate, and fluctuations in element characteristics due to impedance changes in the periphery of elements may occur.

In a semiconductor wafer that is to be divided into chips, a technique is used that forms a guard ring made of metal wiring formed along the chip periphery in order to prevent deterioration of the semiconductor element due to chipping or cracking or infiltration of moisture or mobile ions.

Furthermore, in order to prevent the infiltration of moisture even if there is a defect in a portion of the guard ring, a semiconductor device is proposed that is provided with; a first guard ring which surrounds the periphery of an element formation region; and a second guard ring which is provided between the element formation region and the first guard ring, and which surrounds the periphery of the element formation region; wherein the first guard ring and the second guard ring are connected so as to divide a region between the first guard ring and the second guard ring into a plurality of areas (for example, refer to Japanese Unexamined Patent Application Publication No. 2004-304124 (PTL 1)).

### CITATION LIST

### Patent Literature

PTL 1: Japanese Unexamined Patent Application Publication No. 2004-304124

### SUMMARY OF INVENTION

### Technical Problem

In recent years, although power semiconductors in which GaN is used are the subject of focus as next-generation power semiconductors, it is known that chipping and cracking of such GaN semiconductor substrates may occur more easily than of Si semiconductor substrates under a dicing process which divides the substrates into semiconductor devices.

In a case where a double guard ring structure which is formed of a first guard ring and a second guard ring as in the above-described semiconductor device is applied in such a GaN-based semiconductor device, a problem arises in that leakage current occurs between die bonding material and the semiconductor element when the semiconductor element is die bonded to a metal frame using a die bonding material, such as Ag paste.

As a result of analysis performed by the inventors of GaN-based semiconductor devices with a double guard ring structure, cracks caused by dicing reach as far as the first guard ring, and the conductive die bonding material comes in contact with and is electrically connected to the guard ring. Although the guard ring and the semiconductor element are isolated in a GaN-based semiconductor device with a double guard ring structure, problems arise in the GaN-based semiconductor in that a leakage current occurs between the GaN semiconductor element and the guard ring because it is difficult to control an interface of the GaN-based semiconductor, and, it is found that leakage occurs between the die bonding material and the semiconductor element via the guard ring.

The invention is to provide a high-reliability semiconductor device that suppresses leaking current occurring between the semiconductor elements and the die bonding material and to suppress the infiltration of moisture or movable ions into the semiconductor elements.

### Solution to Problem

In order to resolve the above problem, according to an aspect of the invention, there is provided a semiconductor device including an element formation region in which semiconductor elements are formed on a semiconductor substrate; insulating films formed on at least an outside of the element formation region on the semiconductor substrate; a wall-like first guard ring structure that is formed to surround a periphery of the element formation region on the semiconductor substrate and that extends in a thickness direction of the substrate through the insulating film; and a wall-like second guard ring structure that is formed to surround the periphery of the element formation region between the element formation region and the first guard ring structure on the semiconductor substrate and that extends in the thickness direction of the substrate through the insulating films, in which the first and second guard ring structures are formed of a conductive material, and the first guard ring structure is provided in a state of being insulated from the semiconductor substrate, the element formation region, and the second guard ring structure.

In the semiconductor device of the embodiment, an element isolation region is formed between the second guard ring structure and the element formation region.

In the semiconductor device of the embodiment, each of the first guard ring structure and the second guard ring structure includes annular conductive layers formed to surround the periphery of the element formation region, and disposed with gaps in the thickness direction of the substrate in the insulating films, and an annular contact portion formed in the insulating film to connect between the annular conductive layers.

The annular contact portion is naturally an example, and a wall in which a band-like, a square, and a circular contact portion are combined may be formed.

In the semiconductor device of the embodiment, the second guard ring structure is in contact with at least one of the semiconductor substrate and the semiconductor layers formed on the semiconductor substrate.

In the semiconductor device of the embodiment, the semiconductor elements formed in the element formation region include at least a GaN-based semiconductor layer.

### Advantageous Effects of Invention

As is evident from the above, according to the invention, it is possible to prevent chipping or cracking due to dicing by the first guard ring structure from extending to the second guard ring structure or the semiconductor element, and, furthermore, the first guard ring structure does not generate leakage between the die bonding material which mounts the semiconductor element and the semiconductor element because the first guard ring structure is isolated from the semiconductor substrate, the element formation region, and the second guard ring structure. It is possible to prevent the infiltration of moisture into the semiconductor element due to the second guard ring structure. Accordingly, a high-reliability semiconductor device able to prevent leakage between the semiconductor elements and the die bonding material and to prevent the infiltration of moisture or movable ions into the semiconductor elements can be realized.

### BRIEF DESCRIPTION OF DRAWINGS

FIG. 1 is a plan view illustrating a configuration of a semiconductor device of an embodiment of the invention.

FIG. 2 is a cross sectional view taken along the line II-II in FIG. 1.

### DESCRIPTION OF EMBODIMENTS

Below, the semiconductor device of the invention will be described in detail through an embodiment illustrated in the drawings. Each drawing is simplified in order for the invention to be understood, and the number of metal layers and the like are necessarily examples.

### First Embodiment

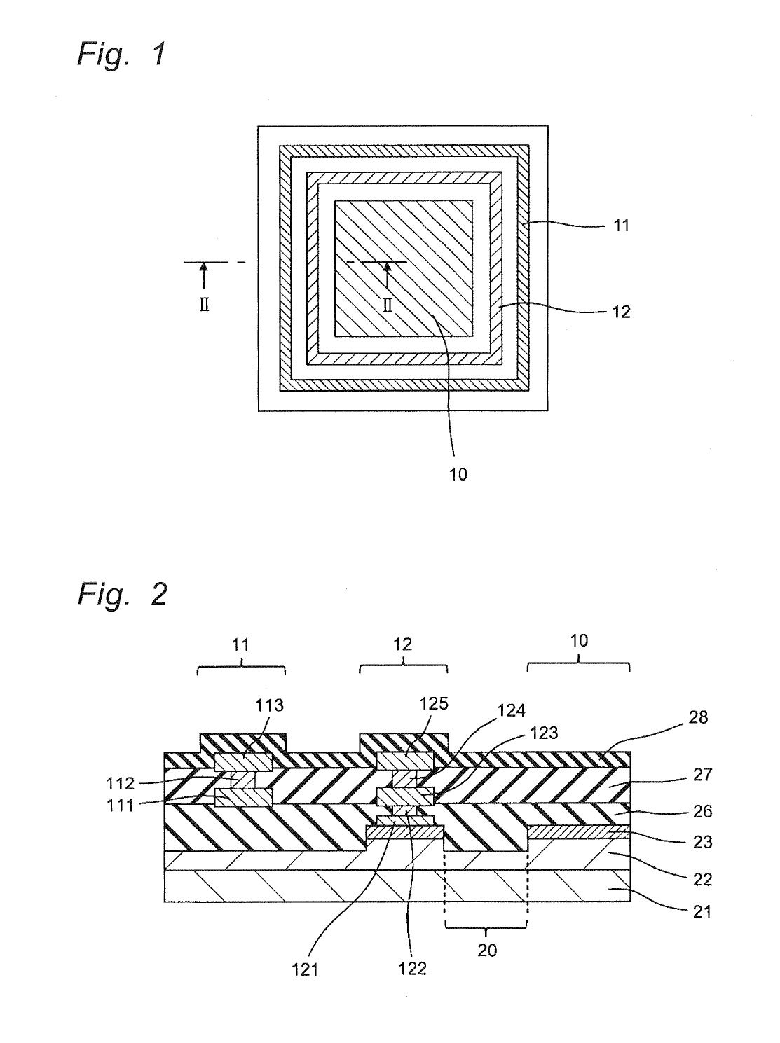

FIG. 1 illustrates the semiconductor device of the first embodiment of the invention. In the semiconductor device of the first embodiment, a GaN-based Hetero-junction Field Effect Transistor (HFET) is formed in the element formation region 10 as a semiconductor element.

In the semiconductor device of the first embodiment of the invention, a wall-like first guard ring structure 11 is formed to surround a square element formation region 10, and a wall-like second guard ring structure 12 is formed to surround the element formation region 10 between the element formation region 10 and the first guard ring structure 11, as illustrated in FIG. 1. The first guard ring structure 11 and the second guard ring structure 12 are not electrically connected to each other and are electrically isolated.

At least one semiconductor element is formed in the element formation region 10. In the embodiment, although the semiconductor element is an HFET, the semiconductor element may be a bipolar transistor, a diode, or the like.

FIG. 2 illustrates a cross sectional view taken along line II-II in FIG. 1, and the semiconductor device includes a silicon substrate 21 as an example of the semiconductor substrate, a GaN-based channel layer 22 formed on the silicon substrate 21, and a GaN-based barrier layer 23 formed on the GaN-based channel layer 22, as illustrated in FIG. 2. Furthermore, insulating films 26 and 27 and a passivation film 28 are stacked in order on the GaN-based channel layer 22. The insulating films 26 and 27 and the passivation film 28 are formed of silicon nitride, silicon oxide or the like. The passivation film 28 prevents the infiltration of moisture or mobile ions from the surface.

The semiconductor element (not shown) is formed on the GaN-based barrier layer 23 in the element formation region 10 by depositing and patterning the insulating film and the metal layer.

The wall-like first guard ring structure 11 extends through the insulating film 27 in the thickness direction of the substrate to the insulating film 26. The first guard ring structure 11 includes a metal layer 111 formed on the insulating film 26, a contact portion 112 formed on the metal layer 111, and a metal layer 113 which is connected to the insulating film 27 via the contact portion 112. The metal layers 111 and 113 are examples of the conductive layer. The metal layers 111 and 113 and the contact portion 112 are each formed in a ring shape to surround the element formation region 10. The first guard ring structure 11 is insulated by the insulating films 26 and 27 and does not come in contact with the silicon substrate 21, the GaN-based channel layer 22, and the GaN-based barrier layer 23. The first guard ring structure 11 and the second guard ring structure 12 are insulated by the insulating film 27, and contact between the first and second guard ring structures 11 and 12 is prevented.

The metal layers 111 and 113 of the first guard ring structure 11 and the contact portion 112 are formed of a metal such as aluminum, copper, and titanium, as an example of the conductive material.

The wall-like second guard ring structure 12 extends through the insulating films 26 and 27 in the thickness direction of the substrate and is in contact with the GaN-based barrier layer 23. The second guard ring structure 12 includes a metal layer 121 formed on the GaN-based barrier layer 23, a contact portion 122 formed on the metal layer 121, a metal layer 123 connected to the insulating film 26 via the contact portion 122, a contact portion 124 formed on the metal layer 123, and a metal layer 125 connected to the insulating film 27 via the contact portion 124. The metal layers 121, 123, and 125 are examples of the conductive layer. The metal layers 121, 123, and 125 and the contact portions 122 and 124 are each formed in a ring shape to surround the element formation region 10. Moisture or mobile ions are prevented from infiltrating into the element formation region 10 from the side wall portion of the semiconductor device by the second guard ring structure 12.

The metal layers 121, 123, and 125 of the second guard ring structure 12 and the contact portions 122 and 124 are formed of a metal such as aluminum, copper, and titanium, as an example of the conductive material. The metal layer 121 that is the lowest portion of the second guard ring structure 12 may be formed so as to remove the GaN-based barrier layer 23 and contact the GaN-based channel layer 22.

The element isolation region 20 is formed between the second guard ring structure 12 and the element formation region 10 by removing the GaN-based barrier layer 23 between the second guard ring structure 12 and the semiconductor element. The element isolation region may be another element isolating structure using ion injection or the like.

Although chipping and cracking may occur when dividing the wafer into semiconductor devices by dicing, it is possible to prevent chipping and cracking from reaching into the interior of the device by forming the first guard ring structure 11 that absorbs the mechanical impact.

Although there are cases where the die bonding material and the first guard ring structure 11 on the outside come in contact because of chipping or cracking due to dicing when the semiconductor device is die bonded to the metal frame using a die bonding material such as Ag paste, leakage does not occur between the second guard ring structure 12 and the die bonding material even if the die bonding material and the first guard ring structure 11 come in contact because the first guard ring structure 11 and the second guard ring structure 12 are electrically isolated.

In particular, in the GaN-based semiconductor device, even if the elements are isolated, it is possible to prevent leakage between the die bonding material and the semiconductor element in a case where leakage occurs between the second guard ring structure 12 and the semiconductor element in the element formation region 10.

It is possible to reliably prevent leakage between the semiconductor element of the element formation region 10 and the second guard ring structure 12 by forming the element isolation region 20 between the second guard ring structure 12 and the element formation region 10.

The first guard ring structure 11 has the annular metal layers 111 and 113 that are formed to surround the periphery of the element formation region 10 and disposed with a gap therebetween in the thickness direction of the substrate in the insulating film 27, and the annular contact portion 112 that is formed in the insulating film 27 so as to connect the metal layers 111 and 113. The second guard ring structure 12 has the metal layer 121 that is formed on the GaN-based barrier layer 23, and the annular metal layers 123 and 125 that are formed to surround the periphery of the element formation region 10 and disposed with a gap therebetween in the thickness direction of the substrate in the insulating film 27, and the annular contact portions 122 and 124 are formed so as to connect the metal layers 121 and 123, and the metal layers 123 and 125, respectively. Accordingly, it is possible to easily form a wall (first guard ring structure 11) that prevents the device from chipping and cracking by extending through the insulating film 27 in the thickness direction of the substrate, and a wall (second guard ring structure 12) that prevents the infiltration of moisture and mobile ions into the insulating films 26 and 27 by extending in the thickness direction of the substrate.

It is possible to reliably prevent the infiltration of moisture or mobile ions by the second guard ring structure 12 being in contact with the GaN-based barrier layer 23 (semiconductor layer) formed on the silicon substrate 21.

In the semiconductor device in which the semiconductor element formed in the element formation region 10 includes a GaN-based semiconductor layer (channel layer 22, barrier layer 23), although chipping and cracking easily occur during the dicing that divides the wafer into the semiconductor devices, it is possible to prevent leakage between the substrate element and the die bonding material and to prevent infiltration of moisture or mobile ions into the semiconductor element by applying the invention, and it is possible to realize a high-reliability GaN-based semiconductor device.

The annular contact portion is only an example, and a wall in which a band-like, a square, and a circular contact portion are combined may be formed.

### Second Embodiment

In the first embodiment, although description was provided using the GaN-based HFET, a silicon semiconductor device may be used as an example of a second embodiment of the invention. The configuration in the second embodiment is the same as in the first embodiment illustrated in FIGS. 1 and 2, with the exception of the semiconductor layer and the semiconductor element.

The semiconductor device of the second embodiment has the same effects as the semiconductor device of the first embodiment.

In the first embodiment and the second embodiment, although a semiconductor device provided with a silicon substrate 21 as the semiconductor substrate is described, the semiconductor device is not limited to the Si substrate, and a sapphire substrate or an SiC substrate may be used, a nitride semiconductor layer may be grown on the sapphire substrate or the SiC substrate, and a nitride semiconductor layer may be grown on a substrate formed of a nitride semiconductor such that an AlGaN layer is grown on a GaN substrate or the like.

Although specific embodiments of the invention are described, the invention is not limited to the first and second embodiments, and it is possible to carry out various modifications within the scope of the invention.

A summary of the invention and the embodiments is as follows.

The semiconductor device of the invention includes an element formation region 10 in which semiconductor elements are formed on a semiconductor substrate 21; insulating films 26 and 27 formed on at least an outside of the element formation region 10 on the semiconductor substrate 21; a wall-like first guard ring structure 11 that is formed to surround a periphery of the element formation region 10 on the semiconductor substrate 21 and that extends in a thickness direction of the substrate through the insulating film 27; and a wall-like second guard ring structure 12 that is formed to surround the periphery of the element formation region 10 between the element formation region 10 and the first guard ring structure 11 on the semiconductor substrate 21 and that extends in the thickness direction of the substrate through the insulating films 26 and 27, in which the first and second guard ring structures 11 and 12 are formed of a conductive material, and the first guard ring structure 11 is provided in a state of being insulated from the semiconductor substrate 21, the element formation region 10, and the second guard ring structure 12.

According to the configuration, even if chipping and cracking occur when dividing a semiconductor wafer into semiconductor devices by dicing, it is possible to prevent infiltration of the chipping and cracking to the interior by forming the first guard ring structure 11, which is made of a conductive material, that absorbs the mechanical impact. Even if the die bonding material and the first guard ring structure 11 come into contact due to chipping or cracking when bonding the semiconductor device to a metal frame using a die bonding material such as Ag paste, since the first guard ring structure 11 provided in a state of being insulated from the semiconductor substrate 21, the element formation region 10, and the second guard ring structure 12 is electrically isolated from the second guard ring structure 12 formed of a conductive material, leakage does not occur between the second guard ring structure 12 and the die bonding material. Moisture or mobile ions are further prevented from infiltrating into the element formation region 10 from the side wall portion of the semiconductor device by the second guard ring structure 12. Accordingly, it is possible to prevent leakage from occurring between the semiconductor element and the die bonding material, possible to prevent the infiltration of moisture into the semiconductor element, and possible to improve the reliability.

In the semiconductor device of the embodiment, an element isolation region 20 is formed between the second guard ring structure 12 and the element formation region 10.

According to the embodiment, it is possible to reliably prevent leakage between the semiconductor element of the element formation region 10 and the second guard ring structure 12 by forming the element isolation region 20 between the second guard ring structure 12 and the element formation region 10.

In the semiconductor device of the embodiment, each of the first guard ring structure 11 and the second guard ring structure 12 includes annular conductive layers 111, 113, 121, 123, and 125 that are formed to surround the periphery of the element formation region 10, and disposed with gaps in the thickness direction of the substrate in the insulating films 26 and 27, and contact portions 112, 122, and 124 formed in the insulating films 26 and 27 to connect between the annular conductive layers 111, 113, 121, 123, and 125, respectively.

According to the embodiment, it is possible to easily form the walls of the first and second guard ring structures 11 and 12 which extend in the thickness direction of the substrate through the insulating films 26 and 27. The first guard ring structure 11 and the second guard ring structure 12 have at least the annular conductive layers 111 and 113, and 121, 123, and 125, respectively, that are formed to surround the periphery of the element formation region 10 and disposed with a gap between the annular conductive layers in the thickness direction of the substrate in the insulating films 26 and 27, and the annular contact portions 112 and 122 and 124 are formed in the insulating films 26 and 27 to connect the annular conductive layers 111 and 113 and 121, 123, and 125, respectively.

In the semiconductor device of the embodiment, the second guard ring structure 12 is in contact with at least one of the semiconductor substrate 21 and the semiconductor layers 22 and 23 formed on the semiconductor substrate 21.

According to the embodiment, it is possible to reliably prevent the infiltration of moisture or mobile ions by the second guard ring structure 12 being in contact with at least one of the semiconductor substrate 21 and the semiconductor layers 22 and 23 formed on the semiconductor substrate 21.

In the semiconductor device of the embodiment, the semiconductor elements formed in the element formation region 10 include at least the GaN-based semiconductor layers 22 and 23.

In the semiconductor device in which the semiconductor element formed in the element formation region 10 includes at least the GaN-based semiconductor layer 22 and 23, although chipping and cracking easily occur during the dicing that divides a semiconductor wafer into semiconductor devices, it is possible to prevent leakage between the substrate element and the die bonding material and to prevent infiltration of moisture or mobile ions into the semiconductor element by applying the invention, and it is possible to realize a high-reliability GaN-based semiconductor device.

### REFERENCE SIGNS LIST

10 element formation region

11 first guard ring structure

12 second guard ring structure

21 silicon substrate

22 GaN-based channel layer

23 GaN-based barrier layer

26, 27 insulating film

28 passivation film

111, 113, 121, 123, 125 metal layer

112, 122, 124 contact portion

1. A semiconductor device, comprising:
an element formation region in which semiconductor elements are formed on a semiconductor substrate;
insulating films formed on at least an outside of the element formation region on the semiconductor substrate;
a wall-like first guard ring structure that is formed to surround a periphery of the element formation region on the semiconductor substrate and that extends in a thickness direction of the substrate through the insulating film; and
a wall-like second guard ring structure that is formed to surround the periphery of the element fomiation region between the element formation region and the first guard ring structure on the semiconductor substrate and that extends in the thickness direction of the substrate through the insulating films,
wherein the first and second guard ring structures are formed of a conductive material, and
the first guard ring structure is provided in a state of being insulated from the semiconductor substrate, the element formation region, and the second guard ring structure.

2. The semiconductor device according to claim 1,
wherein an element isolation region is formed between the second guard ring structure and the element formation region.

3. The semiconductor device according to claim, wherein each of the first guard ring structure and the second guard ring structure includes
annular conductive layers formed to surround the periphery of the element formation region, and disposed with gaps in the thickness direction of the substrate in the insulating films, and
contact portions formed in the insulating films to connect between the annular conductive layers.

4. The semiconductor device according to claim 1,
wherein the second guard ring structure is in contact with at least one of the semiconductor substrate and semiconductor layers formed on the semiconductor substrate.

5. The semiconductor device according to claim 1,
wherein the semiconductor elements formed in the element formation region include at least GaN-based semiconductor layers.
